(19) United States
(12) Patent Application Publication
(10) Pub. No.: US 2024/0171443 A1
(43) Pub. Date: May 23, 2024

(54) WAVEFORM PEAK CLIPPING METHOD AND SYSTEM

(71) Applicant: National Astronomical Observatories, Chinese Academy of Sciences, BEIJING (CN)

(72) Inventors: Ruirui FAN, BEIJING (CN); Ran DUAN, BEIJING (CN); Fei LIU, BEIJING (CN); Xiaoyun MA, BEIJING (CN); Di LI, BEIJING (CN)

(21) Appl. No.: 18/516,951

(22) Filed: Nov. 22, 2023

(30) Foreign Application Priority Data
Nov. 22, 2022 (CN) 202211464900.2

(51) Int. Cl. H04L 27/26; H03M 1/08

(52) U.S. Cl. CPC H04L 27/2623; H03M 1/0845; H04L 27/2634

(57) ABSTRACT

The present invention discloses a waveform peak clipping method and system. The waveform peak clipping method includes: 1) for a complex waveform, building two pulses by a delta function at t=0: a real pulse and an imaginary pulse; 2) performing fast Fourier transform on the two pulses and removing power at a load rate; 3) compensating for missing power and performing inverse fast Fourier transform on results; 4) convolving the pulses built in step 3) with the original waveform; and 5) iterating the convolution process until the amplitudes of the obtained waveforms at all time samples are within a limit range of a digital-to-analog converter during clipping events of all the time samples. The peak clipping method is set in the present invention to limit the amplitude of a bias waveform of a transition edge sensor in any given time sample to a maximum range of the digital-to-analog converter, without affecting the power at the carrier frequencies.

### CROSS-REFERENCE TO RELATED APPLICATIONS

This application claims the benefit and priority of Chinese Patent Application Number 202211464900.2, filed on Nov. 22, 2022, the disclosures of which are incorporated herein by reference in their entireties.

### TECHNICAL FIELD

The present invention relates to the field of radio astronomy data processing, and in particular, to a waveform peak clipping method and system used for a bias waveform of a transition edge sensor.

### BACKGROUND ART

A peak clipping issue in a digital-to-analog converter is as follows:

A bias waveform of a transition edge sensor is a sum of carriers having equal or similar power. Due to relative phases, the amplitude of a waveform at any given time sample may exceed a maximum limit range of the digital-to-analog converter. This produces the peak clipping issue, which ensures that the amplitude of an original waveform at any given time sample is within a limit range of the digital-to-analog converter in some way.

The peak clipping issue is as shown in FIG. 1 and FIG. 2. There are 5 carrier signals having the same power, and their waveforms in the time domain and at some time samples exceed the limit range of the digital-to-analog converter. It is assumed in FIG. 1 and FIG. 2 that the limit range of the digital-to-analog converter is [−1, 1]. At some time samples, the sum of waveforms of the 5 carrier frequencies in the time domain exceeds the limit range of the digital-to-analog converter.

A simplest method is to scale down the original waveform or directly clip peaks, so as to satisfy the limit range of the digital-to-analog converter. However, scaling down the original waveform will decrease the power at the carrier frequencies and the average power of signals by a square of a scale factor. Directly clipping peaks will reduce the power at the carrier frequencies and result in high relative phase errors. Here, a peak-to-average power ratio is used to measure the utilization of the digital-to-analog converter.

To test the effects of the waveform scale-down method and the direct peak clipping method, a complex waveform having a length of 2¹⁷ and including 100 random carrier frequencies and relative phases is generated, and the limit range of the digital-to-analog converter is assumed to be [−1, 1]. Input spectra have power at only carrier frequencies, and magnitudes of the power are all 1/100 (or −20 dB). In the waveform scale-down method, the scale factor is a ratio of a maximum amplitude of the original waveform to a maximum limit of the digital-to-analog converter.

The power spectrum results of the waveforms obtained using the waveform scale-down method and the direct peak clipping method are shown in FIG. 3 and FIG. 4, respectively. The results show that the power at each carrier frequency decreases in both the waveform scale-down method and the direct peak clipping method, and the direct peak clipping method introduces an additional −60 dB level of power at non-carrier frequencies.

### SUMMARY

In response to the problems existing in the prior art, an objective of the present invention is to provide a waveform peak clipping method, which can generate a reliable buffered waveform without affecting power at carrier frequencies and has very low relative phase errors. Another objective of the present invention is to provide a waveform peak clipping system for implementing the above method.

To achieve the above objective, the present invention provides a waveform peak clipping method, including:
1) for a complex waveform, building two pulses by a delta function at t=0: a real pulse and an imaginary pulse;
2) performing fast Fourier transform on the two pulses and removing power at a load rate;
3) compensating for missing power and performing inverse fast Fourier transform on results;
4) convolving the pulses built in step 3) with the original waveform; and
5) iterating the convolution process until the amplitudes of the obtained waveforms at all time samples are within a limit range of a digital-to-analog converter during clipping events of all the time samples.

Further, in step 3), after the inverse fast Fourier transform, a unit scale pulse is obtained at t=0 and a low noise level is obtained at remaining time samples.

Further, in step 5), if the amplitude of a bias waveform in a time sample exceeds the limit range of the digital-to-analog converter, its clipping event is 1, otherwise 0; and the convolved waveform is removed from the original waveform, and the process is iterated until the clipping events of all the time samples are 0.

Further, the digital-to-analog converter has a maximum limit range of CL and a maximum power of CL²/2; and single-channel signals include a total of N_{c} signals with different frequencies, the amplitude of each carrier is equal to AS, the power of each carrier in the single-channel signals is equal to CL²/(2×N_{c}), and the amplitude of each carrier is AS=CL/\sqrt{N_{c}}.

Further, the Nc carrier frequencies of the original waveform have random frequencies and relative phases, and in terms of computational costs, the computational complexity of the peak clipping method is (Nlo(N)), where O( ) represents the complexity of the method, and N represents a data size.

Further, the peak clipping method is specifically as follows:

input: Nc carrier frequencies \vec{F}_{c}, original waveform F(t),
peak clipping level CL;
output: peak-chipped waveform F*(t);
pft = FFT(δ(t = 0))
pft = pft − pft(f = \vec{F}_{c})
p = IFFT(pft)
while number of clipping event > 0 do
if F(tᵢ) > CL then c(tᵢ) = CL − F(tᵢ)
else if F(tᵢ) < −CL then c(tᵢ) = −CL − F(tᵢ)
end
cft = FFT(c)
cftnew = cft × pft
cnew = IFFT(cftnew)
F(tᵢ) = F(tᵢ) + cnew(tᵢ)
end
F*(t) = F(t);

where t represents time, F(t) is an original time-domain waveform, Nc is the number of carrier frequencies in the original waveform, and \vec{F_{c}} is a vector including the Nc carrier frequencies; δ(t=0) is a delta function at t=0, FFT represents Fourier transform, pft represents spectra of signals after the Fourier transform, f represents a frequency, pft(f=\vec{F_{c}}) represents spectra of signals with frequencies equal to the carrier frequencies, p represents time-domain pulse signals obtained after power at the carrier frequencies is removed from the delta function and inverse Fourier transform is performed, tᵢ represents the i^{th} time sample, and the value of c(tᵢ) is a value in the original waveform F(t) that exceeds a peak clipping level at the time sample tᵢ, the c(tᵢ) is negative if the original waveform at tᵢ is higher than a maximum value of the peak clipping level, and the c(tᵢ) is positive if it is lower than a minimum value of the peak clipping level; and c represents all values in the original waveform that exceed a peak clipping level range, cft represents spectra after Fourier transform of c, cftnew represents spectra obtained by multiplying cft and pft in the frequency domain (equivalent to convolving symbol-transformed waveforms beyond the peak clipping range with the built pulse signals in the time domain), and cnew represents time-domain signals after inverse Fourier transform of cftnew.

Further, a method for computing a peak signal-to-noise ratio (SNR) of the peak-chipped waveform is as follows:

input: Nc carrier frequencies \vec{F}_{c}, peak-clipped waveform F(t);
output: peak signal-to-noise ratio SNR of the peak-clipped waveform;
\tilde{F}(f) = FFT(F(t))
Signal = mean(\tilde{F}(f = \vec{F}_{c}))
Noise = mean(\tilde{F}(f ≠ \vec{F}_{c}))
SNR = (Signal/Noise)² × Nc/buffer size

where \tilde{F}(f) represents spectra of the directly peak-chipped waveform F(t) after Fourier transform, mean( ) represents a mean of values in ( ), Signal represents a mean value of carrier frequency signal spectra, Noise represents a mean value of non-carrier frequency signal (noise) spectra, buffer size is a length of the waveform, and SNR is the peak signal-to-noise ratio of the peak-chipped waveform.

Further, the number of clipping events is estimated through a normal distribution, where σ=1/\sqrt{2}, the number of events is equal to the size of a playback buffer, and σ is a standard deviation of the normal distribution.

Further, the peak clipping method reduces power at non-carrier frequencies by allowing predictable power losses at the carrier frequencies, and obtains more power at the carrier frequencies at the cost of computational time.

A waveform peak clipping system, the waveform peak clipping system uses the waveform peak clipping method according to any one of claims 1-9.

The peak clipping method is set in the present invention to limit the amplitude of a bias waveform of a transition edge sensor in any given time sample to the maximum range of the digital-to-analog converter, without affecting the power at the carrier frequencies.

### BRIEF DESCRIPTION OF THE DRAWINGS

FIG. 1 is a waveform diagram of 5 carrier frequencies;

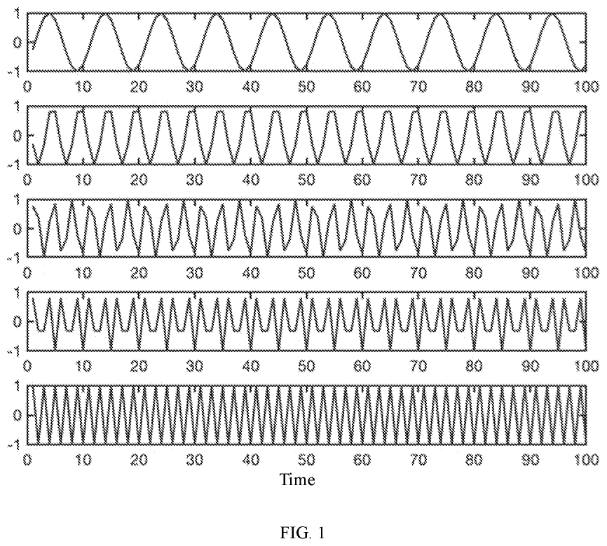

FIG. 2 is a schematic diagram of a sum of waveforms of 5 carrier frequencies in the time domain;

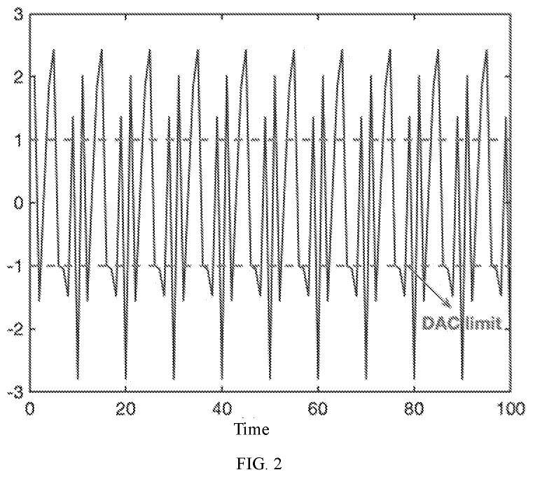

FIG. 3 is a contrast diagram of waveform power spectrum results obtained by a waveform scale-down method and original waveform power spectrum results;

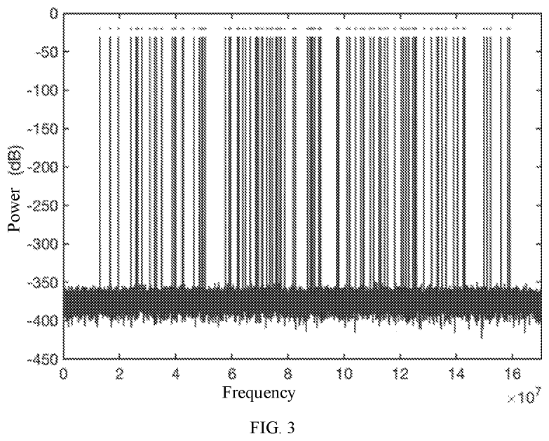

FIG. 4 is a contrast diagram of waveform power spectrum results obtained by a direct peak clipping method and original waveform power spectrum results;

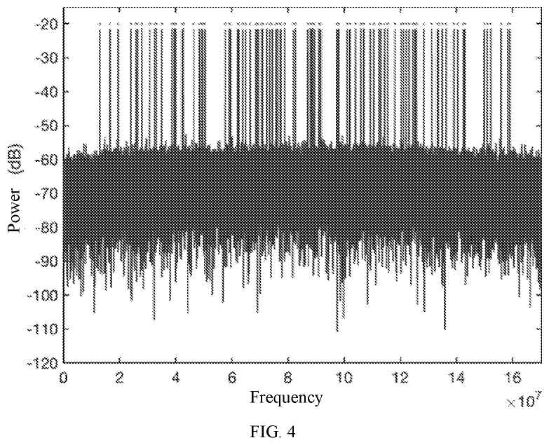

FIG. 5 is a schematic diagram of building two pulses at δ(t=0);

FIG. 6 is a schematic diagram after FFT of δ(t=0);

FIG. 7 is a schematic diagram after power at a load rate is removed and missing power is compensated;

FIG. 8 is a schematic diagram after inverse fast Fourier transform of results;

FIG. 9 is a contrast diagram of power spectrum results of a complex waveform obtained after a peak clipping method and original waveform power spectrum results;

FIG. 10 is a schematic diagram of relative phase errors between a peak-clipped waveform obtained by the waveform scale-down method and an original waveform;

FIG. 11 is a schematic diagram of relative phase errors between a peak-clipped waveform obtained by the direct peak clipping method and an original waveform;

FIG. 12 is a schematic diagram of relative phase errors between a peak-clipped waveform obtained by the peak clipping method and an original waveform;

FIG. 13 is a schematic diagram of contrast of power introduced by the peak clipping method at non-carrier frequencies at a peak clipping level of 1.0;

FIG. 14 is a schematic diagram of contrast of power introduced by the peak clipping method at non-carrier frequencies at a peak clipping level of 2.0;

FIG. 15 is a schematic diagram of contrast of power introduced by the peak clipping method at non-carrier frequencies at a peak clipping level of 3.0.

### DETAILED DESCRIPTION OF THE EMBODIMENTS

The technical solutions of the present invention will be clearly and completely described below with reference to the accompanying drawings. Apparently, the described embodiments are some of, not all of, the embodiments of the present invention. Based on the embodiments in the present invention, all other embodiments obtained by those of ordinary skill in the art without any creative efforts shall fall within the scope of protection of the present invention.

In the description of the present invention, it should be noted that the orientations or positional relationships indicated by the terms “center”, “upper”, “lower”, “left”, “right”, “vertical” “horizontal”, “inner”, “outer”, etc. are based on the orientations or positional relationships shown in the accompanying drawings, are only intended to facilitate the description of the present invention and simplify the description, and are not intended to indicate or imply that a device or element referred to must have a particular orientation or be constructed and operated in a particular orientation, and therefore, the terms cannot be understood as limiting the present invention. Moreover, the terms “first”, “second”, and “third” are merely for the sake of description, and cannot be understood as indicating or implying the relative importance.

In the description of the present invention, it should be noted that, unless otherwise specified and defined, the terms “mounted”, “connected”, and “connection” should be generally understood, for example, the “connection” may be fixed connection, detachable connection, integral connection, mechanical connection, electrical connection, direct connection, connection by a medium, or internal communication between two elements. For those of ordinary skill in the art, the specific meanings of the terms in the present invention may be understood according to specific situations.

Specific implementations of the present invention will be described in detail below with reference to the accompanying drawings. It should be understood that the specific implementations described here are only intended to illustrate and explain the present invention and are not intended to limit the present invention.

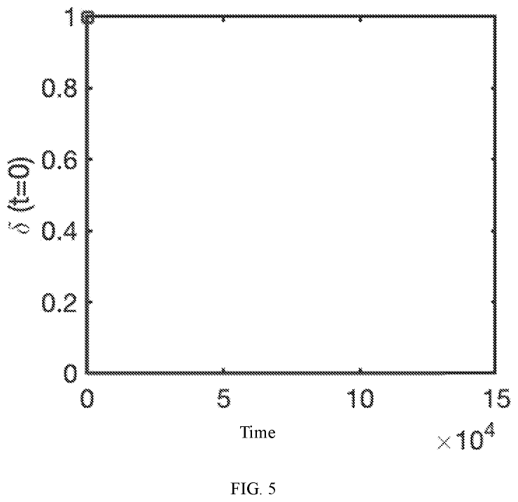

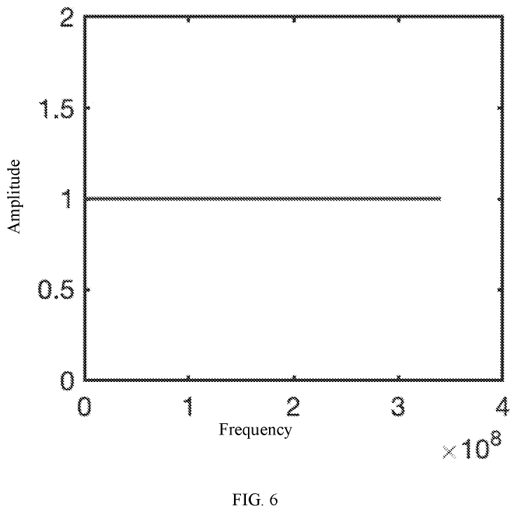

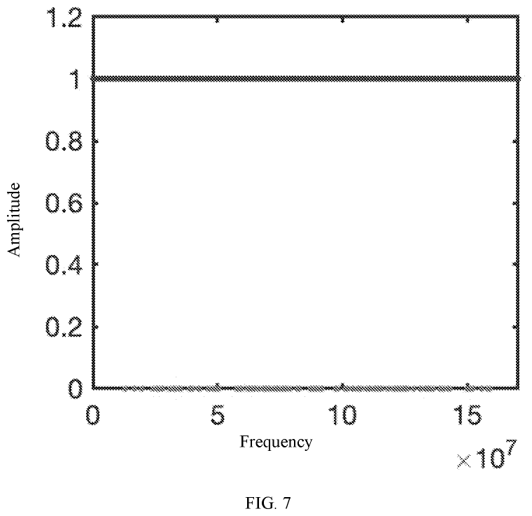

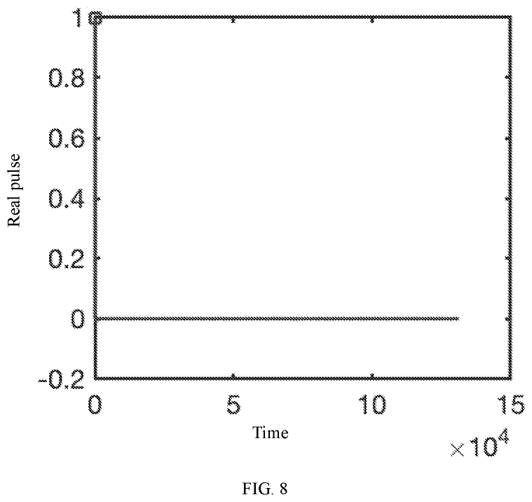

The present invention relates to a waveform peak clipping method, which builds pulses without power at carrier frequencies, so that the power in each carrier is not affected by peak clipping. For a complex waveform, its real part and imaginary part need to be processed simultaneously. A specific solution is to build two pulses by a delta function at t=0: a real pulse and an imaginary pulse, perform fast Fourier transform on the two pulses, remove power at a load rate, compensate for a sum of missing power, and perform inverse fast Fourier transform on results. In this case, a unit scale pulse is obtained at t=0 and a low noise level is obtained at remaining time samples. The process of building pulses is shown in FIGS. 5, 6, 7, and 8.

The built pulses are convolved with the original waveform and clipping events are recorded simultaneously. If the amplitude of a bias waveform in a time sample exceeds a limit range of a digital-to-analog converter, its clipping event is 1, otherwise 0. The convolved waveform is removed from the original waveform, and the process is iterated until the clipping events of all time samples are 0. Then, the amplitudes of the obtained waveforms in all the time samples are within the limit range of the digital-to-analog converter.

If a maximum limit range of the digital-to-analog converter is CL, namely, if a maximum amplitude of single-channel signals is CL, a maximum power is CL²/2. If the single-channel signals include a total of N_{c} signals with different frequencies and the amplitude of each carrier is equal to AS, in order to make the power of each carrier in the single-channel signals equal to CL²/(2×N_{c}), the amplitude of each carrier should satisfy AS=CL/\sqrt{N_{c}}.

It is assumed that the Nc carrier frequencies of the original waveform have random frequencies and relative phases. In terms of computational costs, the computational complexity of the waveform peak clipping method of the present invention is O(N log(N)). The first character of O(N log(N)) is an uppercase letter O, indicating that when the data volume increases by N times, the time for the method increases by N log(N) times.

The waveform peak clipping method of the present invention is as the following method 1, where the peak clipping level is the limit range CL of the digital-to-analog converter.

Method 1: waveform peak clipping method

| | input: Nc carrier frequencies \vec{F}_{c}, original waveform F(t), peak |
|---|---|
| | clipping level CL |
| | output: peak-chipped waveform F*(t) |
| 1 | pft= FFT(δ(t = 0)) |
| 2 | pft = pft − pft(f = \vec{F}_{c}) |
| 3 | p = IFFT(pft) |
| 4 | while number of clipping event > 0 do |
| 5 | if F(tᵢ) > CL then c(tᵢ) = CL − F(tᵢ) |
| 6 | else if F(tᵢ) < −CL then c(tᵢ) = −CL − F(tᵢ) |
| 7 | end |
| 8 | cft = FFT(c) |
| 9 | cftnew = cft × pft |
| 10 | cnew = IFFT(cftnew) |
| 11 | F(tᵢ) = F(tᵢ) + cnew(tᵢ) |
| 12 | end |
| 13 | F*(t) = F(t) |

Here, t represents time, F(t) is an original time-domain waveform, Nc is the number of carrier frequencies in the original waveform, and \vec{F_{c}} is a vector including the Nc carrier frequencies; δ(t=0) is a delta function at t=0, FFT represents Fourier transform, pft represents spectra of signals after the Fourier transform, f represents a frequency, pft(f=\vec{F_{c}}) represents spectra of signals with frequencies equal to the carrier frequencies, p represents time-domain pulse signals obtained after power at the carrier frequencies is removed from the delta function and inverse Fourier transform is performed, t₁ represents the i^{th} time sample, and the value of c(tᵢ) is a value in the original waveform F(t) that exceeds a peak clipping level at the time sample tᵢ, the c(tᵢ) is negative if the original waveform at tᵢ is higher than a maximum value of the peak clipping level, and the c(tᵢ) is positive if it is lower than a minimum value of the peak clipping level; and c represents all values in the original waveform that exceed a peak clipping level range, cft represents spectra after Fourier transform of c, cftnew represents spectra obtained by multiplying cft and pft in the frequency domain (equivalent to convolving symbol-transformed waveforms beyond the peak clipping range with the built pulse signals in the time domain), and cnew represents time-domain signals after inverse Fourier transform of cftnew. “while number of clipping event >0 do” represents: when the number of clipping events >0.

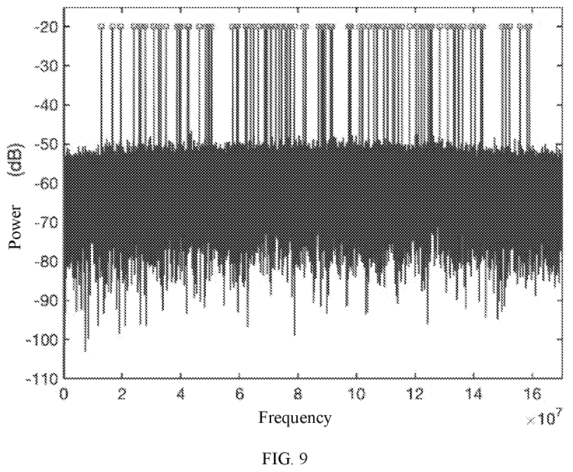

In the waveform peak clipping method of the present invention, a waveform with each carrier frequency power equal to 1/Nc can be generated within a few seconds. For a complex waveform having a length of 2¹, 100 random carrier frequencies and relative phases are included, and the limit range of the digital-to-analog converter is assumed to be [−1, 1]. Input spectra have power at only carrier frequencies, and magnitudes of the power are all 1/100 (or −20 dB). The power spectrum results of the complex waveform obtained by the peak clipping method are shown in FIG. 9. It can be seen that the same power is obtained at each carrier frequency as the carrier frequency of the original waveform, at the cost of introducing additional −50 dB power at non-carrier frequencies.

For the impact of waveform peak clipping on its power spectra, we mainly focused on the power spectra of approximately 100 carriers with zero power at all other frequencies. If no peak clipping is done, computational errors introduced during forward and reverse FFTs are computed under double floating point precision, where a noise level of 10⁻¹⁸ is introduced in this analysis. In this application, three carrier frequency mechanisms are explored: (a) random placement, (b) equidistant, and (c) equidistant, with a spacing “noise” term equal to ⅕ of a bin interval. Under the limitations, each point in a (time domain) playback buffer is independent of the next point and can be well described through a normal distribution. On the other hand, the equidistant limitation is the best situation, and for a given peak clipping level, although the carriers themselves become wider, lower background noise will be introduced. The noise spacing situation is very similar to the random situation of a selected noise value. Only under the limit of extremely low noise can noisy intervals approach the equidistant situation. In all situations, 2¹⁶ playback buffers are selected, corresponding to 2¹⁵ independent frequencies, among which 144 are filled. 1000 to 10000 playback buffers can be achieved per minute.

In a test, taking the direct peak clipping method as an example, a method for computing a peak signal-to-noise ratio (SNR) of the peak-chipped waveform is as follows:

input: Nc carrier frequencies \vec{F}_{c}, peak clipping level CL;
output: peak signal-to-noise ratio SNR of the waveform after
direct peak clipping;
for all Fc do
Ø = U(0,2π)
Ac = e^{Ø}/\sqrt{Nc}
end for
F(t) = IFFT(Ac)
if F(tᵢ) > CL then F(tᵢ) = CL
else if F(tᵢ) < −CL then F(tᵢ) = −CL
end if
\tilde{F}(f) = FFT(F(t))
Signal = mean(\tilde{F}(f = \vec{F}_{c}))
Noise = mean(\tilde{F}(f ≠ \vec{F}_{c}))
SNR = (Signal/Noise)² × Nc/buffer size

Here, ∅=U(0,2π) represents Nc phases randomly generated within (0,2π), e is a natural constant, Ac represents spectra of an original waveform, F(t) represents a time-domain original waveform obtained by inverse Fourier transform of Ac, tᵢ represents the i^{th} time sample, \tilde{F}(f) represents spectra of the directly peak-chipped waveform F(t) after Fourier transform, mean( ) represents a mean of values in ( ), Signal represents a mean value of carrier frequency signal spectra, Noise represents a mean value of non-carrier frequency signal (noise) spectra, buffer size is a length of the waveform, and SNR is the peak signal-to-noise ratio of the peak-chipped waveform.

Power is evenly distributed to all carriers. For 144 carriers, the amplitude of each carrier is 1/24 relative to a full scale, and each carrier has a random phase. The playback buffers generated in this way always have an RMS value of 1/\sqrt{2} (total power) before peak clipping, and are very similar to a normal distribution when randomly placed. The problem at this point is what happens to the power spectral density (PSD) of the playback buffers if values higher than a specific level are “peak-chipped”. In this case, the power from the carriers will be dispersed to other frequency ranges, thereby affecting SNR (signal-to-noise ratio). Considering the PSD of the three systems as a function of peak clipping level, white noise can well describe noise in both random and noisy situations.

The number of clipping events can be estimated through a normal distribution, where σ=1/\sqrt{2}, the number of events is equal to the size of a playback buffer, and σ is a standard deviation of the normal distribution. Through peak clipping values, approximately half of implementations have no any clipping event, so SNR is not affected in a digital sense.

As a contrast, the same original waveform in the peak clipping method is tested by a waveform scale-down method and a direct peak clipping method.

In the waveform scale-down method, it is assumed that a scale factor is SF, and each carrier has an amplitude of AS=CL/\sqrt{N_{c}} and a power of AS²/2. Since the amplitude of waveforms of N_{c}, carriers added in the time domain will be greater than CL at a time sample (the amplitude of the added waveforms is approximately ⅓×AS×N_{c}=⅓×CL/\sqrt{N_{c}}×N_{c}=⅓×CL×\sqrt{N_{c}}, and the scale factor is SF=⅓×\sqrt{N_{c}}), the amplitude of each carrier is divided by the scale factor to limit the added waveforms to be within the range of the digital-to-analog converter. At this point, the amplitude of each carrier becomes AS′=AS/SF, and the power becomes AS′²/2=AS²/(2×SF²), that is, the power of each carrier is reduced by SF² times. In the direct peak clipping method, values in the added waveforms that exceed the maximum limit range CL of the digital-to-analog converter are directly set to equal to CL, and values below a minimum limit range −CL of the digital-to-analog converter are directly set to equal to −CL.

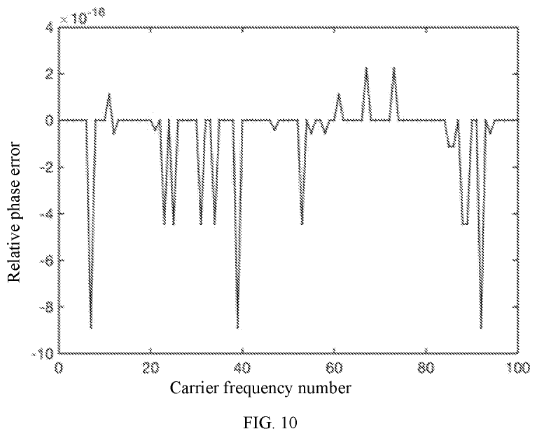

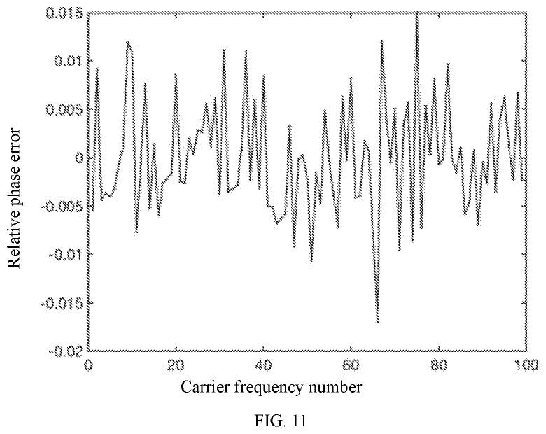

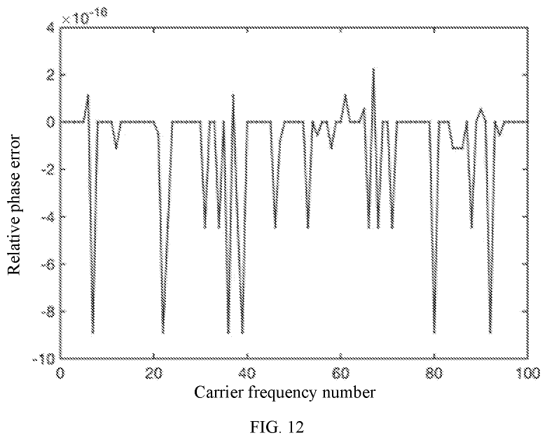

Table 1 compares the peak power, average power, and peak-to-average power ratio of waveforms obtained using the waveform scale-down method, the direct peak clipping method, and the peak clipping method in the present invention. The waveform scale-down method results in a decrease in both carrier power and average power by the square of the scale factor. Compared with the waveform scale-down method and the direct peak clipping method, the peak clipping method can maintain the power at each carrier frequency unaffected by peak clipping. FIGS. 10, 11, and 12 show relative phase errors between peak-clipped waveforms and original waveforms obtained by the three peak clipping methods. It can be seen that the relative phase errors of the waveforms obtained by the waveform scale-down method and the peak clipping method are on an order of 10⁻¹⁶, while the direct peak clipping method causes a relatively large relative phase error.

TABLE 1
Contrast of peak (carrier) power, average power,
and peak-to-average power ratio of waveforms
obtained by three peak clipping methods:

| | Peak (carrier) | Average | Peak-to-average |
|---|---|---|---|
| Method | power (dB) | power (dB) | power ratio |
| Original waveform | −20 | −20 | 1 |
| Waveform scale-down | −30.4209 | −30.4209 | 1 |
| method | | | |
| Direct peak clipping | −21.4788 | −21.3481 | 0.9939 |
| method | | | |
| Peak clipping method | −20 | −20 | 1 |

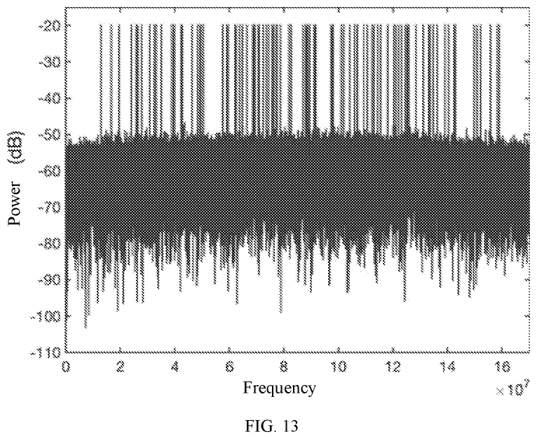

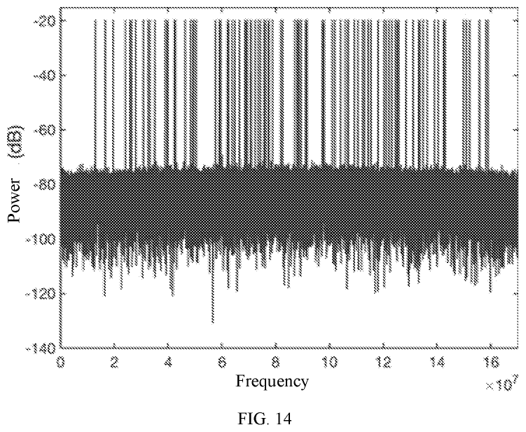

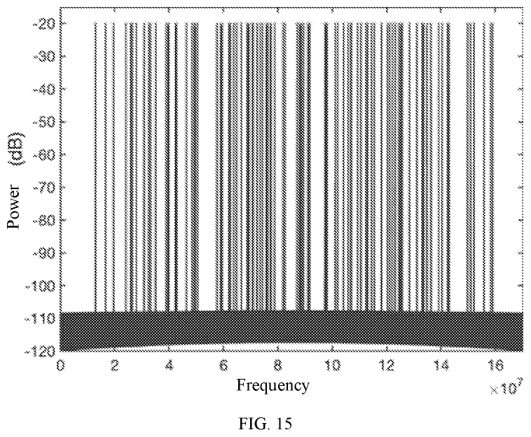

In order to further test the peak clipping method, we explored the impact of peak clipping on waveform power and treated power spectra as a function of peak clipping level (maximum limit range of the digital-to-analog converter). The results are shown in FIGS. 13, 14, FIG. 15. We can see that as the peak clipping level increases, with values of 1.0, 2.0, and 3.0, the peak clipping method introduces less power at non-carrier frequencies, with values of −50 dB, −80 dB, and −110 dB, respectively.

As mentioned earlier, the waveform scale-down method maximizes power losses at carrier frequencies, while the direct peak clipping method has low power losses at carrier frequencies, but introduces additional power at non-carrier frequencies, and has high relative phase errors. Although the peak clipping method also introduces power at non-carrier frequencies, it can maintain the power of each carrier unaffected by peak clipping and has low relative phase errors.

In the technical solution of the present invention, there is a compromise between the finally output power at the carrier frequencies and (1) computational time and (2) power level at the non-carrier frequencies. Although the peak clipping method does not affect the power at the carrier frequencies, significant power at non-carrier frequencies that are still within the bandwidth of a transition edge sensor resonator may indirectly affect the performance of the resonator. If noise at the non-carrier frequencies is proven to be important, the power at the non-carrier frequencies can be reduced by allowing predictable power losses at the carrier frequencies. Second, more power can be obtained at the carrier frequencies at the cost of computational time. An increase of 20% in power at a carrier frequency takes about 1 minute. Third, the peak clipping method actually introduces additional clipping events at the beginning, that is, the method slowly diverges and then quickly converges. This is because the clipping events in the original waveform that exceed the peak clipping level the most initially amplify the low noise level in the built pulses. The amplification effect causes the peak clipping method of the present invention to introduce additional clipping events in previous iterations, so that the values in the waveform that are originally within the range of the digital-to-analog converter exceed the limit range of the digital-to-analog converter. Therefore, the total number of clipping events increases, and the method slowly diverges. However, as the number of iterations increases, the additional values introduced after each peak clipping are small enough to not exceed the limit range of the digital-to-analog converter, and the amplification effect will not affect the number of clipping events anymore, so the number of clipping events will rapidly decrease and the method will converge quickly.

1. A waveform peak clipping method, characterized in that the waveform peak clipping method comprises:
1) for a complex waveform, building two pulses by a delta function at t=0: a real pulse and an imaginary pulse;
2) performing fast Fourier transform on the two pulses and removing power at a load rate;
3) compensating for missing power and performing inverse fast Fourier transform on results;
4) convolving the pulses built in step 3) with the original waveform; and
5) iterating the convolution process until the amplitudes of the obtained waveforms at all time samples are within a limit range of a digital-to-analog converter during clipping events of all the time samples.

2. The waveform peak clipping method according to claim 1, characterized in that in step 3), after the inverse fast Fourier transform, a unit scale pulse is obtained at t=0 and a low noise level is obtained at remaining time samples.

3. The waveform peak clipping method according to claim 1, characterized in that in step 5), if the amplitude of a bias waveform in a time sample exceeds the limit range of the digital-to-analog converter, its clipping event is 1, otherwise 0; and the convolved waveform is removed from the original waveform, and the process is iterated until the clipping events of all the time samples are 0.

4. The waveform peak clipping method according to claim 1, characterized in that the digital-to-analog converter has a maximum limit range of CL and a maximum power of CL²/2; and single-channel signals comprise a total of N_{c} signals with different frequencies, the amplitude of each carrier is equal to AS, the power of each carrier in the single-channel signals is equal to CL²/(2×N_{c}), and the amplitude of each carrier is AS=CL/\sqrt{N_{c}}.

5. The waveform peak clipping method according to claim 1, characterized in that the Nc carrier frequencies of the original waveform have random frequencies and relative phases, and in terms of computational costs, the computational complexity of the peak clipping method is O(N log(N)), wherein O( ) represents the complexity of the method, and N represents a data size.

6. The waveform peak clipping method according to claim 1, characterized in that the peak clipping method is specifically as follows:
input: Nc carrier frequencies \vec{F}_{c}, original waveform F(t), peak clipping level CL;
output: peak-chipped waveform F*(t);
pft= FFT(δ(t = 0))
pft = pft − pft(f = \vec{F}_{c})
p = IFFT(pft)
while number of clipping event > 0 do
if F(tᵢ) > CL then c(tᵢ) = CL − F(tᵢ)
else if F(tᵢ) < −CL then c(tᵢ) = −CL − F(tᵢ)
end
cft = FFT(c)
cftnew = cft × pft
cnew = IFFT(cftnew)
F(tᵢ) = F(tᵢ) + cnew(tᵢ)
end
F*(t) = F(t);
wherein t represents time, F(t) is an original time-domain waveform, Nc is the number of carrier frequencies in the original waveform, and \vec{F_{c}} is a vector comprising the Nc carrier frequencies;
δ(t=0) is a delta function at t=0, FFT represents Fourier transform, pft represents spectra of signals after the Fourier transform, f represents a frequency, pft(f=\vec{F_{c}}) represents spectra of signals with frequencies equal to the carrier frequencies, p represents time-domain pulse signals obtained after power at the carrier frequencies is removed from the delta function and inverse Fourier transform is performed, tᵢ represents the i^{th} time sample, and the value of c(tᵢ) is a value in the original waveform F(t) that exceeds a peak clipping level at the time sample tᵢ, the c(tᵢ) is negative if the original waveform at tᵢ is higher than a maximum value of the peak clipping level, and the c(tᵢ) is positive if it is lower than a minimum value of the peak clipping level; and
c represents all values in the original waveform that exceed a peak clipping level range, cft represents spectra after Fourier transform of c, cftnew represents spectra obtained by multiplying cft and pft in the frequency domain, cnew represents time-domain signals after inverse Fourier transform of cftnew, and IFFT represents inverse Fourier transform.

7. The waveform peak clipping method according to claim 1, characterized in that a method for computing a peak signal-to-noise ratio (SNR) of the peak-chipped waveform is as follows:
input: Nc carrier frequencies \vec{F}_{c}, peak-clipped waveform F(t);
output: peak signal-to-noise ratio SNR of the peak-clipped waveform;
\tilde{F}(f) = FFT(F(t))
Signal = mean(\tilde{F}(f = \vec{F_{c}}))
Noise = mean(\tilde{F}(f ≠ \vec{F_{c}}))
SNR = (Signal/Noise)₂ × Nc/buffer size
wherein \tilde{F}(f) represents spectra of the directly peak-chipped waveform F(t) after Fourier transform, mean( ) represents a mean of values in ( ), Signal represents a mean value of carrier frequency signal spectra, Noise represents a mean value of non-carrier frequency signal spectra, buffer size is a length of the waveform, and SNR is the peak signal-to-noise ratio of the peak-chipped waveform.

8. The waveform peak clipping method according to claim 1, characterized in that the number of clipping events is estimated through a normal distribution, wherein α=1/\sqrt{2}, the number of events is equal to the size of a playback buffer, and σ is a standard deviation of the normal distribution.

9. The waveform peak clipping method according to claim 1, characterized in that the peak clipping method reduces power at non-carrier frequencies by allowing predictable power losses at the carrier frequencies, and obtains more power at the carrier frequencies at the cost of computational time.

10. A waveform peak clipping system, characterized in that the waveform peak clipping system uses the waveform peak clipping method according to claim 1.

11. A waveform peak clipping system, characterized in that the waveform peak clipping system uses the waveform peak clipping method according to claim 2.

12. A waveform peak clipping system, characterized in that the waveform peak clipping system uses the waveform peak clipping method according to claim 3.

13. A waveform peak clipping system, characterized in that the waveform peak clipping system uses the waveform peak clipping method according to claim 4.

14. A waveform peak clipping system, characterized in that the waveform peak clipping system uses the waveform peak clipping method according to claim 5.

15. A waveform peak clipping system, characterized in that the waveform peak clipping system uses the waveform peak clipping method according to claim 6.

16. A waveform peak clipping system, characterized in that the waveform peak clipping system uses the waveform peak clipping method according to claim 7.

17. A waveform peak clipping system, characterized in that the waveform peak clipping system uses the waveform peak clipping method according to claim 8.

18. A waveform peak clipping system, characterized in that the waveform peak clipping system uses the waveform peak clipping method according to claim 9.
